(19) United States
(12) Patent Application Publication
(10) Pub. No.: US 2006/0214313 A1
(43) Pub. Date: Sep. 28, 2006

(54) Die attach methods and apparatus

(76) Inventors: Ruel B. Pieda, Cavite (PH); Carmelito M. Libay, Cavite (PH); Andrew Gomez, Cavite (PH); Sandeep B. Sane, Chandler, AZ (US); Timothy M. Takeuchi, Chandler, AZ (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/089,050

(22) Filed: Mar. 24, 2005

(51) Int. Cl. H01L 23/28

(52) U.S. Cl. 257/787

(57) ABSTRACT

A method for packaging a die includes attaching the die to a substrate using a plurality of pieces of discontinuous die attach material, and injecting a mold compound at the interface between the die and the substrate.

### TECHNICAL FIELD

The inventive subject matter is related to attaching a die to a substrate or to another die.

### BACKGROUND INFORMATION

Integrated circuits have been manufactured for many years. Manufacturing integrated circuits involves integrating various active and passive circuit elements into a piece of semiconductor material, referred to as a die. The die is attached to a package substrate to form a ceramic or plastic package. The die is attached using a die attach material The die attach material is used to hold the die and spacer assembly together as the die is wire bonded to the package substrate. The die attach material prevents the die from tilting during wire bonding. The die attach material can also be used between dies in a stacked package.

In current packages, a single sheet of die attach material having dimensions that are substantially the same or slightly smaller than the dimensions of the die is used to attach the die to the package substrate. Once the wire bonding is completed, a mold compound is injected around the die or dies (stacked) to encapsulate the die or dies. The mold compound engulfs the die or dies, any spacer, and the die attach material. The mold compound fills any gaps between the spacer, die attach material and the die or dies. The die attach material has very high coefficient of thermal expansion (CTE) (˜100-150 ppm), while mold compound and spacer have CTEs less than 20 ppm. The die is formed primarily of silicon. Silicon has a CTE of 3 ppm. The mismatch in CTEs of these materials leads to local bending of dies, and high compressive stresses in the active regions of die. These compressive stresses in turn cause poor performance of the circuitry on the die. For example, the poor performance induced by these compressive stresses can cause a significant yield loss in a set of dies including flash memory.

In addition, using a single piece of die attach material that is about the same size as the die also can trap moisture during the molding process. As the package is subjected to thermo mechanical loading, the trapped moisture expands, causing stress to build up in the interface. This can cause layer separation or delamination. Bottom die cracking is also commonly observed on packages utilizing a die attach material having substantially the same dimensions as the die. Moisture trapped during the molding process causes air voids in the die and film interface. These voids become high stress areas when the package undergoes thermo mechanical loading. The location of voids normally corresponds to the crack initiation points. Furthermore, mechanical stressing after assembly can cause silicon mobility changes that affect the overall memory block performance and other electrical performance of the circuitry on a die.

### BRIEF DESCRIPTION OF THE DRAWINGS

Embodiments of the invention are pointed out with particularity in the appended claims. However, a more complete understanding of the inventive subject matter may be derived by referring to the detailed description when considered in connection with the figures, wherein like reference numbers refer to similar items throughout the figures, and:

FIG. 1 is a top view of a printed circuit board having a package that is formed according to an example embodiment.

FIG. 2 illustrates a top view of a package, according to an example embodiment.

FIG. 3 illustrates a cross-sectional view of the package along line 3-3 shown in FIG. 2, according to an example embodiment.

FIG. 4 illustrates an alternative cross-sectional view of the package, according to an example embodiment.

FIG. 5 illustrates a top view of a package, according to an example embodiment.

FIG. 6 illustrates a cross-sectional view of the package along line 6-6 shown in FIG. 5, according to an example embodiment.

FIG. 7 illustrates a top view of a package, according to an example embodiment.

FIG. 8 illustrates a cross-sectional view of the package along line 8-8 shown in FIG. 7, according to an example embodiment.

FIG. 9 is a flow diagram of a method of attaching a die to a substrate, according to an example embodiment.

FIG. 10 is a flow diagram of a method of attaching a die to a substrate, according to an example embodiment.

FIG. 11 is a flow diagram of a method of attaching a die to a substrate, according to an example embodiment.

The description set out herein illustrates various embodiments of the invention, and such description is not intended to be construed as limiting in any manner.

### DETAILED DESCRIPTION

In the following detailed description of the preferred embodiments, reference is made to the accompanying drawings that form a part hereof, and in which are shown by way of illustration specific embodiments in which the inventive subject matter can be practiced. The embodiments illustrated are described in sufficient detail to enable those skilled in the art to practice the teachings disclosed herein. Other embodiments can be utilized and derived therefrom, such that structural and logical substitutions and changes can be made without departing from the scope of the inventive subject matter. The following detailed description, therefore, is not to be taken in a limiting sense, and the scope of various embodiments of the invention is defined only by the appended claims, along with the full range of equivalents to which such claims are entitled.

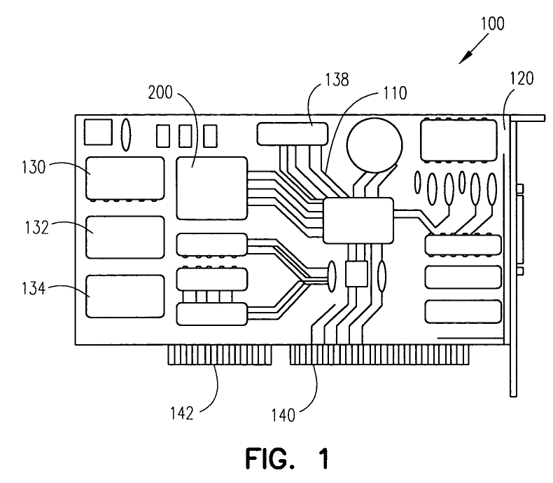

FIG. 1 is a top view of a printed circuit board 100. The printed circuit board 100 includes an electrical device or package or component 200 having formed according to an embodiment of the invention. The printed circuit board (“PCB”) 100 is a multi-layer plastic board that includes patterns of printed circuits on one or more layers of insulated material. The patterns of conductors correspond to the wiring of an electronic circuit formed on one or more of the layers of the printed circuit board 100. The printed circuit board 100 also includes electrical traces 110. The electrical traces 110 can be found on an exterior surface 120 of the printed circuit board 100, and also can be found on the various layers within the printed circuit board 100. Printed circuit boards also include through holes (not shown in FIG. 1) which are used to interconnect traces on various layers of the printed circuit board 100. The printed circuit board 100 can also include planes of metallized materials such as ground planes, power planes, or voltage reference planes (not shown in FIG. 1).

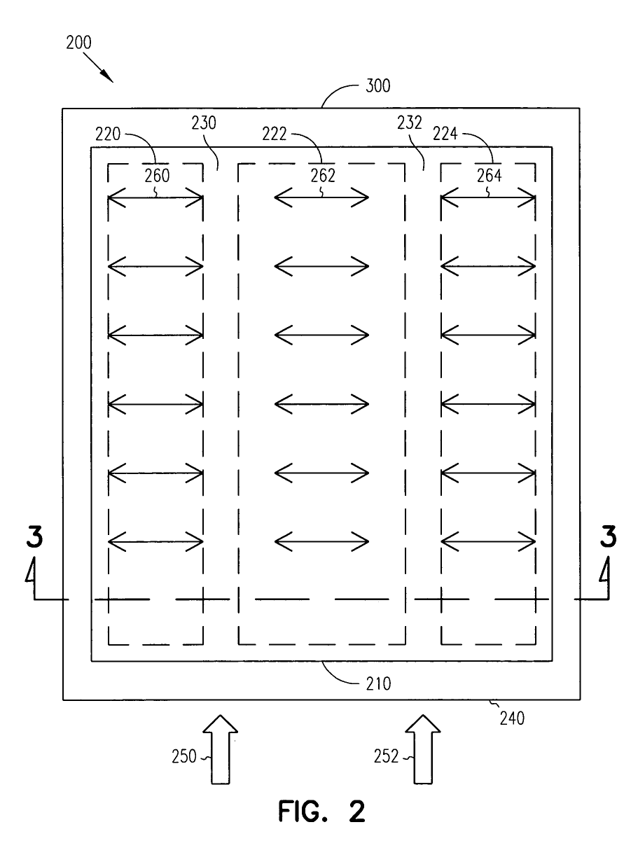

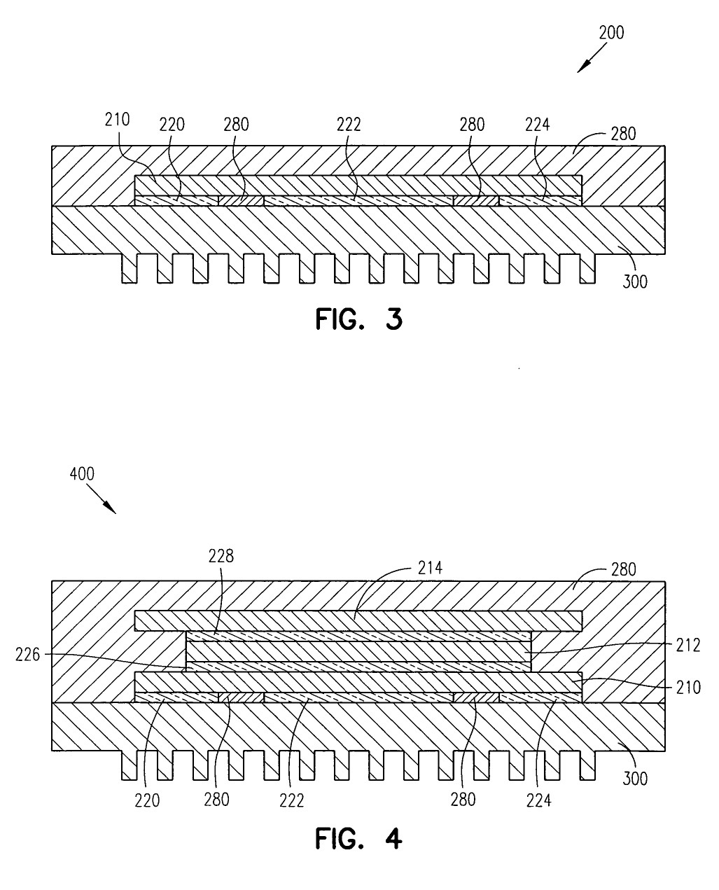

The printed circuit board 100 is also populated with various components 130, 132, 134, 138, 200. The components 130, 132, 134, 138, 200 can be either discrete components, or semiconductor chips which include thousands of transistors. The components 130, 132, 134, 138, 200 can use any number of technologies to connect to the exterior surface 120 of the printed circuit board 100. For example, pins may be inserted into plated through holes, or pins may be extended through the printed circuit board 100. An alternative technology is surface mount technology, where an electrical component, such as package or component 200, mounts to an array of pads on the exterior surface 120 of the printed circuit board 100. For example, package or component 200 could be a ball grid array package or device that has an array of balls or bumps that interact or are connected to a corresponding array of pads on the exterior surface 120 of the printed circuit board 100. The package or component 200 is formed according to an embodiment of this invention. The die is electrically coupled to a substrate 300 (see FIGS. 2 and 3) to form a package or component 200 that can be attached to the printed circuit board 100.

The printed circuit board 100 can also include traces 110 for making external connections to other electrical or electronic devices. In an embodiment of the invention, the package or component 200 is a central processing chip or microprocessor, that can be used as a controller or for any other function. Although the printed circuit board 100 shown is a daughter board, the printed circuit board 100 could also be a motherboard, and the component or electrical device could be the main processing unit for a computer. In some computing environments, multiple main processing units can be used.

As shown in FIG. 1, the printed circuit board 100 includes a first edge connector 140 and a second edge connector 142. As shown in FIG. 1 there are external traces, such as electrical trace 110, on the external surface 120 of the printed circuit board 100, that connect to certain of the outputs associated with the first edge connector 140. Other traces that connect with the edge connectors 140, 142 will have traces internal to the printed circuit board 100.

FIGS. 2-8 illustrate various example embodiments for attaching one or more dies to a substrate using a die attach material. The details of these embodiments is set forth in the paragraphs that follow. It should be noted that in FIGS. 2-8 that the interconnect bumps, wires or other electrical connections between the dies or to individual dies have been omitted from the figures for the sake of clarity. Omitting the interconnections reduces the complexity of the figures and allows a better understanding of the various example embodiments set forth in FIGS. 2-8.

FIG. 2 illustrates a top view of a package 200, according to an example embodiment. FIG. 3 illustrates a cross-sectional view of the package 200 along line 3-3 shown in FIG. 2, according to an example embodiment. Referring to both FIGS. 2 and 3, the package 200 includes a substrate 300, a die 210, a first die attach material 220 attached to the die 210 and to the substrate 300, a second die attach material 222 attached between the die 210 and the substrate 300, and a third die attach material 224 attached between the die 210 and the substrate 300. The first, second and third portions of die attach material 220, 222, and 224, respectively are spaced so as to form a first vent or gas passageway 230 and a second vent or gas passageway 232. A mold compound 280 is interposed between the first die attach material 220 and the second die attach material 222, and between the second die attach material 222 and the third die attach material 224. The mold compound 280 substantially fills the vent or gas passageway 230 and the vent or gas passageway 232. The mold compound 280 also envelopes or encapsulates the die 210. In other words, the mold compound 280 and the substrate 210 substantially surround and isolate the die 210. The die attach material 220, 222, 224 can be a film or a paste.

As shown in FIG. 2, hot, melted mold compound is injected from an edge 240 of the package 200, as depicted by arrow 250 and arrow 252. The die attach material outgases, as depicted by arrows such as 260, 262, 264 that are located within the boundaries of the die attach material 220, 222, 224, respectively. The die attach material 220, 222, 224 heats and outgases moisture or other gases during the molding process. The vents or gas passageways 230, 232, provide a passageway for the moisture and other gases during the molding process, or during the process where liquid mold compound 280 is injected into the vents or gas passageways 230, 232 and over the die 210. With the vents or gas passageways 230, 232, substantially all the gases outgassing from the die attach materials 220, 222, 224, are allowed to escape rather than being trapped. If the gasses are trapped, the resulting package 200 develops a void. As the package 200 is subjected to thermal mechanical loading cycles, such as during the operation and inoperation of the printed circuit or system associated with the printed circuit board 100, the void or trapped moisture or air expands, causing stress to build up at the interface between the mold compound 280 and the void. The expansion of the void can result in layer separation or delamination at or near the die 210 and substrate 300 interface. In addition, expansion of voids can also result in the bottom of the die 210 cracking.

The location of the stress raisers, namely the location of the voids, normally corresponds to crack initiation points in the bottom of the die 210. Attaching a first die attach material 220, a second die attach material 222, and a third die attach material 224 so as to form vents or gas passageways 230, 232 substantially reduces the possibility of formation of voids during the encapsulation process or during the process where molding compound 280 is injected into the vent or passageways to encapsulate the die 210. The use of first die attach material 220, second die attach material 222, and third die attach material 224 also reduces stress due to differences in the coefficient of thermal expansion for the die attach material, the coefficient of thermal expansion for the die 210, and the coefficient of thermal expansion for the mold compound 280 when compared to a system in which a single continuous piece of die attach material having a footprint substantially equal to the footprint of the die 210 is used to attach the die 210 to the substrate 300. By using several discontinuous pieces of die attach material, such as the first die attach material 220, the second die attach material 222, and the third die attach material 224, the stresses within the package are reduced. One of the stresses that is reduced within the package or component 200 is the in-plane compressive stress in an active region of the die 210. Reducing the in-plane compressive stress also reduces the effect of that stress on carrier mobility within the semiconductor and transconductance phenomenon (gₘ shift) and improves the overall performance of the circuitry on the die 210.

It should be noted that the die attach material is not limited to the geometry shown in FIGS. 2 and 3. Other geometries of die attach materials can also be used, including thinner strips of die attach material, tiles of die attach material, smaller squares of die attach material, and the like. Since the coefficient of thermal expansion of the die attach material is high relative to both the mold compound 280 and the die 210, the stresses caused by the difference in the coefficient of thermal expansion of the materials can be minimized when a minimum amount of die attach material is used to attach the die 210 to the substrate 300 that is sufficient to hold the die 210 in place during a wire bonding step, as well as injecting liquid mold compound 280 to encapsulate the die 210.

FIG. 4 illustrates an alternative cross-sectional view of a package 400, according to an example embodiment. The package 400 includes a first die 210, a second die 212, and a third die 214. In addition to die attach material 220, 222, 224, also included in the package 400 is a fourth piece of die attach material 226 and a fifth piece of die attach material 228. In other words, the package 400 includes a series of stacked dies 210, 212, 214. A fourth piece of die attach material 226 having a footprint substantially equal to the footprint of the second die 212 is used to attach the second die 212 to the first die 210. The fifth piece of die attach material 228 is used to attach the second die 212 to the third die 214. The molding process or injecting the hot molten mold compound 280 over the dies 210, 212, 214 is accomplished in the same way as discussed in FIG. 2. The main difference shown here is that the use of the first die material 220, the second die material 222, and the third portion of die material 224, arranged to form vents, is equally applicable in a stacked configuration of dies 210, 212, 214. The remaining dies 212, 214 can be attached with continuous pieces of die attach material 226, 228 that have the same footprint as the second die 212. It should be noted that the stresses that are reduced include the von Mises stress and the bottom die's maximum principle stress and strains. Stress of the die active circuit layer is also lowered and stress oscillation for the segments of die attach material also reduces the package's risk to transconductance phenomenon (gₘ shift). The reduction in the von Mises stress and the bottom die's maximum principle stress makes the resulting packages, such as package 200 and package 400, more robust against delamination and die cracking.

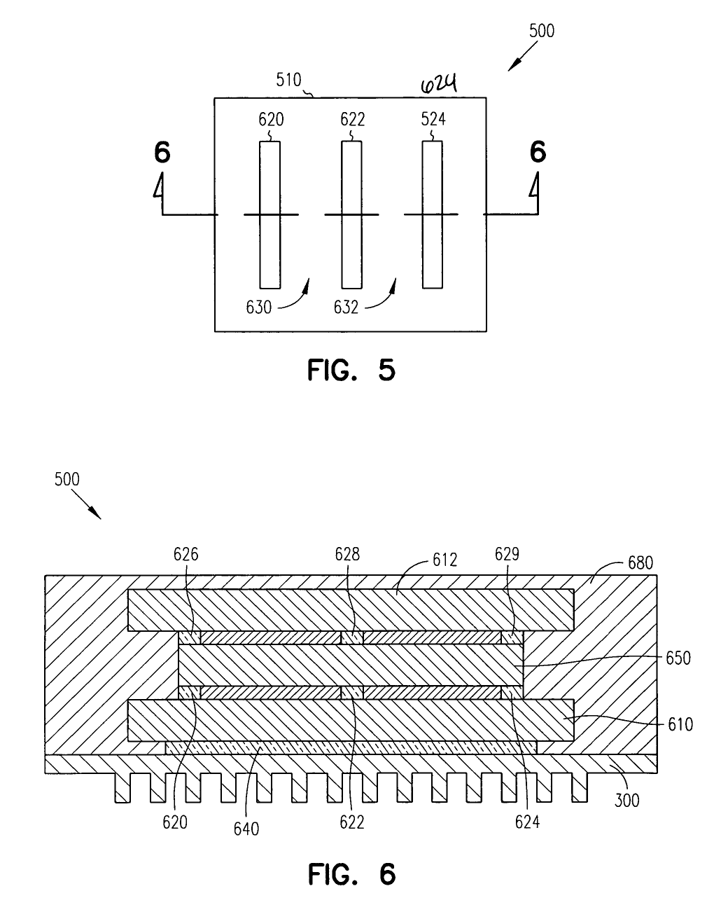

FIG. 5 illustrates a top view of a package 500, according to an example embodiment. FIG. 6 illustrates a cross-sectional view of the package 500 along line 6-6 shown in FIG. 5, according to an example embodiment. Referring to both FIGS. 5 and 6, the package 500 includes a substrate 300, a first die 610, a second die 612, and spacer 650. The package 500 also includes a first die attach material 620, a second die attach material 622, a third die attach material 624, a fourth die attach material 626, a fifth die attach material 628, and a sixth die attach material 629. The various die attach material portions are segmented or discontinuous. As shown in FIG. 5, the die attach material 620, 622, 624 are each a relatively thin strip of die attach material when compared to the die attach material shown in FIG. 2. The die attach material 620, 622, 624 are arranged to form vent or gas passageways 630, 632. The vent or gas passageways 630, 632 are substantially parallel to one another. The first die attach material 620, the second die attach material 622, and the third die attach material 624 are used to attach the die 610 to the spacer 650. The fourth die attach material 626, the fifth die attach material 628, and the sixth die attach material 629 are used to attach the second die 612 to the spacer 650. A continuous piece of die attach material 640 is used to attach the first die 610 to the substrate 300. It should be noted that discontinuous strips or portions of die attach material could also be used to attach the first die 610 to the substrate 300. A mold compound 680 is injected from an edge 510 of the package 500 to allow outgassing of the various die attach materials 620, 622, 624, 626, 628, 629 through the vents, such as vents or gas passageways 630, 632, during the molding process. The mold compound 680 envelopes or surrounds both the first die 610 and the second die 612.

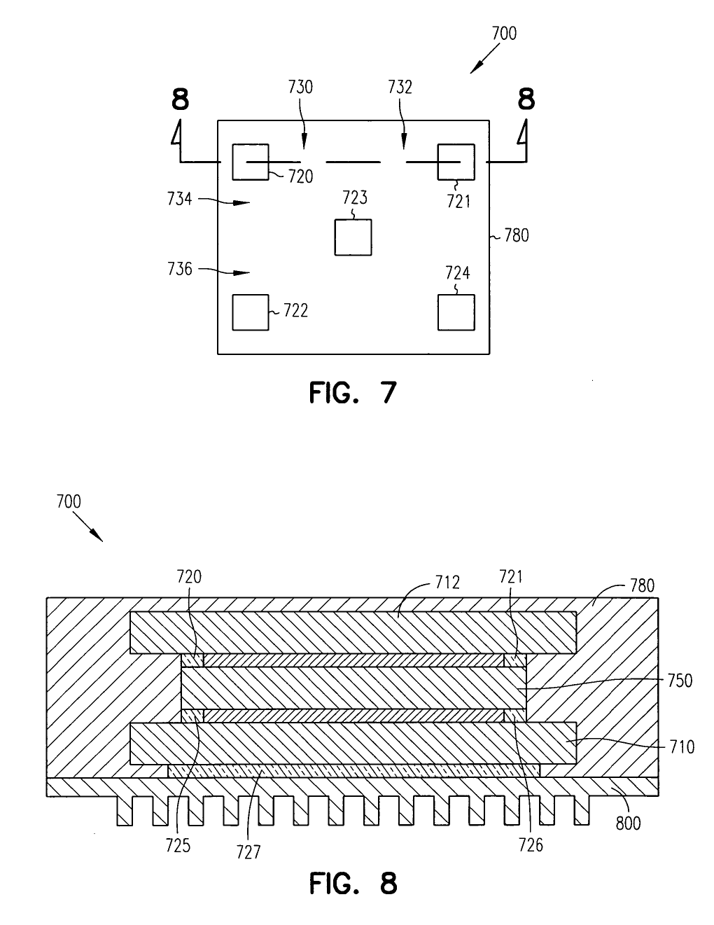

FIG. 7 illustrates a top view of a package 700, according to an example embodiment. FIG. 8 illustrates a cross-sectional view of the package 700 along line 8-8, shown in FIG. 7, according to an example embodiment. The package includes a first die 710 and a second die 712 and a spacer 750, which are attached to a substrate 800 and encapsulated with a mold compound 780. Spacer 750 is attached to the first die 710 with five patches of die attach material. The second die 712 is similarly attached to the spacer 750 with five patches of die attach material. One level of the patches of die attach material is shown in FIG. 7. FIG. 7 shows a die attach material 720, a die attach material 721, a die attach material 722, a die attach material 723, and a die attach material 724. The various portions of die attach material 720, 721, 722, 723, 724 are attached near the corners of the spacer 750 and near the center of the spacer 750. The portions of die attach material 720, 721, 722, 723, 724 are placed so as to form a vent or gas passageway 730, a vent or gas passageway 732, a vent or gas passageway 734, and a vent or gas passageway 736. The vent passageways 730, 732 are parallel with another, while the vent passageways 734, 736 are also parallel with one another and traverse the vent gas passageways 730, 732. The portions of die attach material 720, 721, 722, 723, 724 can be thought of as being in a tiled layout. The portions or pieces of die attach material 720, 721, 722, 723, 724 are positioned so that gas vents are formed and so that a mold compound 780 can be injected from a direction transverse to an edge of the die 712, 710 or an edge of the spacer 750 to allow the die compound to flow into the spaces between the die and the substrate 800, as well as the spaces between the two dies 710, 712 and the spacer 750. As the mold compound 780 flows, the gas that comes from any of the portions of die attach material is able to flow through the various vents 730, 732, 734, 736. The package 700 shown in FIG. 8 includes an additional die attach material portion 725 and an additional die attach material portion 726 used to attach the spacer 750 to the first die 710. An additional piece of die attach material 727 is used to attach the first die 710 to the substrate 800 in the package 700. It should be noted that amount of die attach material used is optimized when the minimum amount of material used to attach the die 712, 710 and the spacer 750 holds the die during the wire bonding process and during the injection of mold compound 780. In this way, the amount of outgassing that will occur is minimized, and the amount of stress and strain placed upon the various dies by the differing coefficients of thermal expansion between the die attach material 720, 721, 722, 723, 724, 725, 726, and 727 and the die and the mold compound is also minimized.

An apparatus includes a substrate, a first die, and a second die attached to the first die. The apparatus also includes a first die attach material attached to the first die and to the substrate, and a second die attach material attached to the first die and to the substrate. A mold compound is interposed between the first die attach material and the second die attach material. In one embodiment of the invention, the apparatus also includes a third die attach material attached to the first die and to the second die, and a fourth die attach material attached to the first die and to the second die. Mold compound is interposed between the third die attach material and the fourth die attach material. In another example embodiment, the apparatus also includes a spacer attached to the first die and the second die. A third die attach material is attached to the first die and to the spacer, and a fourth die attach material is attached to the first die and to the spacer. Mold compound is interposed between the third die attach material and the fourth die attach material. In still another example embodiment, the apparatus includes a fifth die attach material attached to the second die and to the spacer, and a sixth die attach material attached to the second die and to the spacer. Mold compound is interposed between the fifth die attach material and the sixth die attach material.

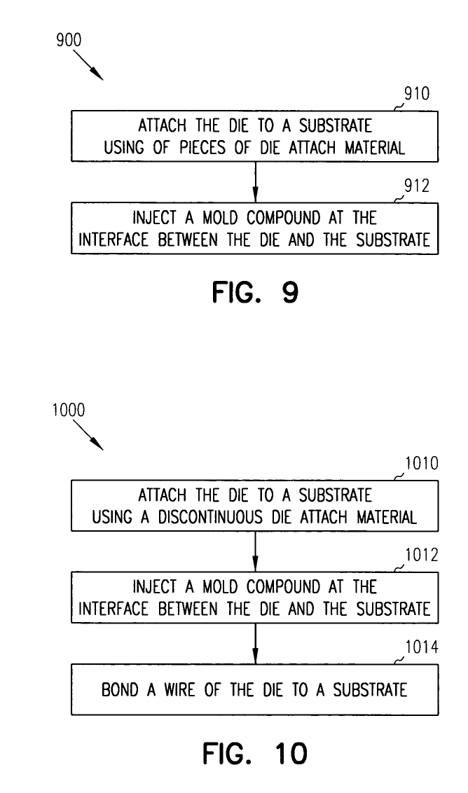

FIG. 9 is a flow diagram of a method 900 of attaching a die to a substrate, according to an example embodiment. The method 900 for packaging a die includes attaching the die to a substrate using a plurality of pieces of die attach material 910, and injecting a mold compound at the interface between the die and the substrate 912. The method further includes placing the plurality of pieces of die attach material to provide a free space between the pieces of die attach material. The space between the plurality of pieces of die attach material provides at least one gas vent pathway. The at least one gas vent pathway is substantially filled with mold compound as the mold compound is injected at the interface between the die and the substrate. In some embodiments, the plurality of pieces of die attach material provide a plurality of gas vent pathways. In some embodiments, placing the plurality of pieces of die attach material provides a plurality of gas vent pathways, including a pair of substantially parallel gas vent pathways. In still other embodiments, the plurality of gas vent pathways includes a first gas vent pathway transverse to a second gas vent pathway. At least two of the plurality of gas vent pathways are substantially filled with mold compound as the mold compound is injected at the interface between the die and the substrate. In some embodiments, injecting the mold compound at the interface between the die and the substrate includes injecting the mold compound from an edge of the die.

FIG. 10 is a flow diagram of a method of attaching a die to a substrate, according to an example embodiment. The method 1000 for packaging includes attaching the die to a substrate using a discontinuous die attach material 1010, and injecting a mold compound at the interface between the die and the substrate 1012. The discontinuous die attach material includes a first piece of die attach material and a second piece of die attach material spaced from the first piece of die attach material. In one example embodiment, the first piece and the second piece of die attach material are strips of die attach material. In another example embodiment, the first piece and the second piece of die attach material are polygon-shaped pieces of die attach material having a surface area smaller than a major surface of the die. The discontinuous die attach material can be a paste or a film. The method also includes bonding a wire of the die to a substrate 1014. In other example embodiments, other electrical connections can be used such as ball bonding, bump bonding, tab tape bonding, surface attach, and the like. The amount of die attach material used to attach the die is sufficient to hold the die in place during bonding and during injection of the mold compound.

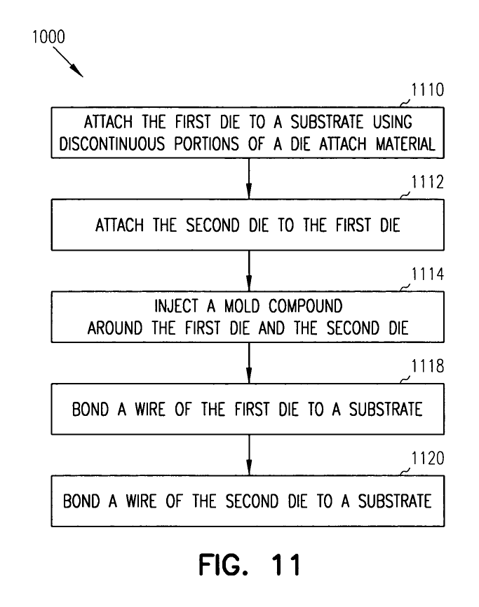

FIG. 11 is a flow diagram of a method of attaching a die to a substrate, according to an example embodiment. The method 1100 for packaging a first die and a second die includes attaching the first die to a substrate using discontinuous portions of a die attach material 1110, attaching the second die to the first die 1112, and injecting a mold compound around the first die and the second die 1114. In an example embodiment, attaching the second die to the first die includes attaching the second die to a spacer. In another example embodiment, attaching the second die to the first die includes using discontinuous portions of a die attach material. In one embodiment, the method 1100 includes stacking the first die and the second die. In one embodiment, injecting a mold compound around the first die and the second die 1114 includes injecting the mold compound from a selected edge of the first die and the second die. The method also includes bonding a wire of the first die to the substrate 1118, and bonding a wire of the second die to the substrate 1120.

The foregoing description of the specific embodiments reveals the general nature of the inventive subject matter sufficiently that others can, by applying current knowledge, readily modify and/or adapt it for various applications without departing from the generic concept, and therefore such adaptations and modifications are intended to be comprehended within the meaning and range of equivalents of the disclosed embodiments.

It is to be understood that the phraseology or terminology employed herein is for the purpose of description and not of limitation. Accordingly, the embodiments of the invention are intended to embrace all such alternatives, modifications, equivalents and variations as fall within the spirit and broad scope of the appended claims.

What is claimed is:

1. A method for packaging a die comprising:
attaching the die to a substrate using a plurality of pieces of die attach material; and
injecting a mold compound at the interface between the die and the substrate.

2. The method of claim 1 further comprising placing the plurality of pieces of die attach material to provide a free space between the plurality of pieces of die attach material.

3. The method of claim 1 further comprising placing the plurality of pieces of die attach material to provide at least one gas vent pathway.

4. The method of claim 3 wherein the at least one gas vent pathway is substantially filled with mold compound as the mold compound is injected at the interface between the die and the substrate.

5. The method of claim 1 further comprising placing the plurality of pieces of die attach material to provide a plurality of gas vent pathways.

6. The method of claim 5 wherein placing the plurality of pieces of die attach material to provide a plurality of gas vent pathways includes forming a pair of substantially parallel gas vent pathways.

7. The method of claim 5 wherein placing the plurality of pieces of die attach material to provide a plurality of gas vent pathways includes forming a first gas vent pathway transverse to a second gas vent pathways.

8. The method of claim 5 wherein at least two of the plurality of gas vent pathways are substantially filled with mold compound as the mold compound is injected at the interface between the die and the substrate.

9. The method of claim 1 wherein injecting the mold compound at the interface between the die and the substrate includes injecting the mold compound from an edge of the die.

10. A method for packaging comprising:
attaching the die to a substrate using a discontinuous die attach material; and
injecting a mold compound at the interface between the die and the substrate.

11. The method of claim 10 wherein the discontinuous die attach material includes a first piece of die attach material and a second piece of die attach material spaced from the first piece of die attach material.

12. The method of claim 11 wherein the first piece and the second piece of die attach material are strips of die attach material.

13. The method of claim 11 wherein the first piece and the second piece of die attach material are polygon-shaped pieces of die attach material having a surface area smaller than a major surface of the die.

14. The method of claim 10 wherein the discontinuous die attach material is a paste.

15. The method of claim 10 wherein the discontinuous die attach material is a film.

16. The method of claim 10 further comprising bonding a wire of the die to a substrate, wherein an amount of die attach material used to attach the die is sufficient to hold the die in place during bonding and during injection of the mold compound.

17. A method for packaging a first die and a second die comprising:
attaching the first die to a substrate using discontinuous portions of a die attach material;
attaching the second die to the first die; and
injecting a mold compound around the first die and the second die.

18. The method of claim 17 wherein attaching the second die to the first die includes attaching the second die to a spacer.

19. The method of claim 17 wherein attaching the second die to the first die includes using discontinuous portions of a die attach material.

20. The method of claim 17 wherein attaching the second die to the first die includes stacking the first die and the second die.

21. The method of claim 17 wherein injecting a mold compound around the first die and the second die includes injecting the mold compound from a selected edge of the first die and the second die.

22. The method of claim 17 further comprising:
bonding a wire of the first die to the substrate; and
bonding a wire of the second die to the substrate.

23. A system comprising:
a substrate;
a die;
a plurality of discrete portions of die attach material having a gap therebetween attached to the die and to the substrate; and
a mold compound interposed between the first die attach material and the second die attach material.

24. The system of claim 23 wherein the die attach material is a film.

25. The system of claim 23 wherein the die attach material is a paste.

26. The system of claim 23 wherein the mold compound substantially surrounds the die.

27. An apparatus comprising:
a substrate;
a first die;
a first die attach material attached to the first die and to the substrate;
a second die attach material attached to the first die and to the substrate;
a second die attached to the first die; and
a mold compound interposed between the first die attach material and the second die attach material.

28. The apparatus of claim 27 further comprising:
a third die attach material attached to the first die and to the second die;
a fourth die attach material attached to the first die and to the second die; and
a mold compound interposed between the third die attach material and the fourth die attach material.

29. The apparatus of claim 27 further comprising:
a spacer attached to the first die and the second die;
a third die attach material attached to the first die and to the spacer; and
a fourth die attach material attached to the first die and to the spacer, the mold compound interposed between the third die attach material and the fourth die attach material.

30. The apparatus of claim 29 further comprising:
a fifth die attach material attached to the second die and to the spacer; and
a sixth die attach material attached to the second die and to the spacer, the mold compound interposed between the fifth die attach material and the sixth die attach material.
